(19) United States
(12) Patent Application Publication
(10) Pub. No.: US 2007/0045694 A1
(43) Pub. Date: Mar. 1, 2007

(54) Method of selecting a RRAM memory material and electrode material

(75) Inventor: Sheng Teng Hsu, Camas, WA (US)

Correspondence Address: ROBERT D. VARITZ, 4915 S.E. 33RD PLACE, PORTLAND, OR, 97202, US

(73) Assignee: Sharp Laboratories of America, Inc.

(21) Appl. No.: 11/215,484

(22) Filed: Aug. 30, 2005

(51) Int. Cl. H01L 29/76

(52) U.S. Cl. 257/296; 257/298; 257/379; 257/537

(57) ABSTRACT

A method of determining a memory material and an associated electrode material for use in a RRAM device includes selecting a memory material having an inner orbital having less than a full quota of electrons and a narrow, outer conductive orbital; and selecting an associated electrode material for injecting a packet of electrons into the selected memory material when subjected to a narrow-width electric pulse, and which recovers the packet of electrons when subjected to a large-width electric pulse.

### FIELD OF THE INVENTION

This invention relates to non-volatile memory, and specifically to selection of material suitable for use in resistance random access memory (RRAM) devices as memory and electrode materials.

### BACKGROUND OF THE INVENTION

A number of materials have been demonstrated to have reversible resistance change properties, making them suitable for use in RRAM devices, such as Pr_{0.7}Ca_{0.3}MnO₃ (PCMO), SrTiO₃, SrZrO₃, SrTiZrO₃, PbZr₁₋ₓTiₓO₃, NiO, ZrO₂, Nb₂O₅, TiO₂, and Ta₂O₅.

Liu et al., Electric-pulse-induced reversible resistance change effect in magnetoresistive films, App. Phys. Let. Vol. 76, No. 19, May 2000, p. 2749-2751, reported reversible resistance change properties in colossal magnetoresistive (CMR) materials, such as perovskites, having a structure of ReBMnO₃, where Re is a rare earth element and B is an alkaline ion.

Beck et al., Reproducible switching effect in thin oxide files for memory applications, App. Phys. Let. Vol 77, No. 1, Jul. 2000, p. 139-141, noted reversible resistance change properties in oxides, such as Nb₂O₅, Al₂O₃, Ta₂O₅ and NiO.

Watanabe et al., Current-driven insulator-conductor transition and nonvolatile memory in Chromium-doped SrTiO₃ single crystals, App. Phys. Let. Vol. 78, No. 23, Jun. 2001, p. 3738-3740, noted reversible resistance change properties in chromium-doped SrTiO₃ devices.

Baikalov et al., Field-driven hysteretic and reversible resistive switch at the Ag—Pr_{0.7}Ca_{0.3}MnO₃ interface, App. Phys. Let. Vol. 83, No. 5, Aug. 2003, p. 957-959, described work in Ag/Pr_{0.7}Ca_{0.3}MnO₃/YBa₂Cu₃O₇ sandwiches.

Tsui et al., Field-induced resistance switching in metal-oxide interfaces, App. Phys. Let. Vol. 85, No. 2, Jul., 2004, p. 317-319, described reversible resistance change properties in interfacial layers of 10 nm and less.

Baek et al., Highly Scalable Non-volatile Resistive Memory using Simple Binary Oxide Driven by Asymmetric Unipolar Voltage Pulse, 2004 IEDM p. 587-590, describes reversible resistance change properties using chromium-doped SrTi(Zr)O₃, PCMO, and PbZn_{0.52}Ti_{0.48}O₃.

### SUMMARY OF THE INVENTION

A method of selecting a memory material and an associated electrode material for use in a RRAM device includes selecting a memory material having an inner orbital having less than a full quota of electrons and a narrow, outer conductive orbital; and selecting an associated electrode material for injecting a packet of electrons into the selected memory material when subjected to a narrow-width electric pulse, and which recovers the packet of electrons when subjected to a large-width electric pulse.

It is an object of the invention to determine what materials are suitable for use in RRAM as memory and electrode materials.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a schematic diagram of a PCMO layer epitaxially deposited on a YBCO electrode.

FIG. 2 depicts a pulse width window of the structure of FIG. 1.

FIG. 3 is a schematic diagram of a PCMO layer spin-coated on a YBCO electrode.

FIG. 4 depicts a pulse width window of the structure of FIG. 3.

### DETAILED DESCRIPTION OF THE PREFERRED EMBODIMENTS

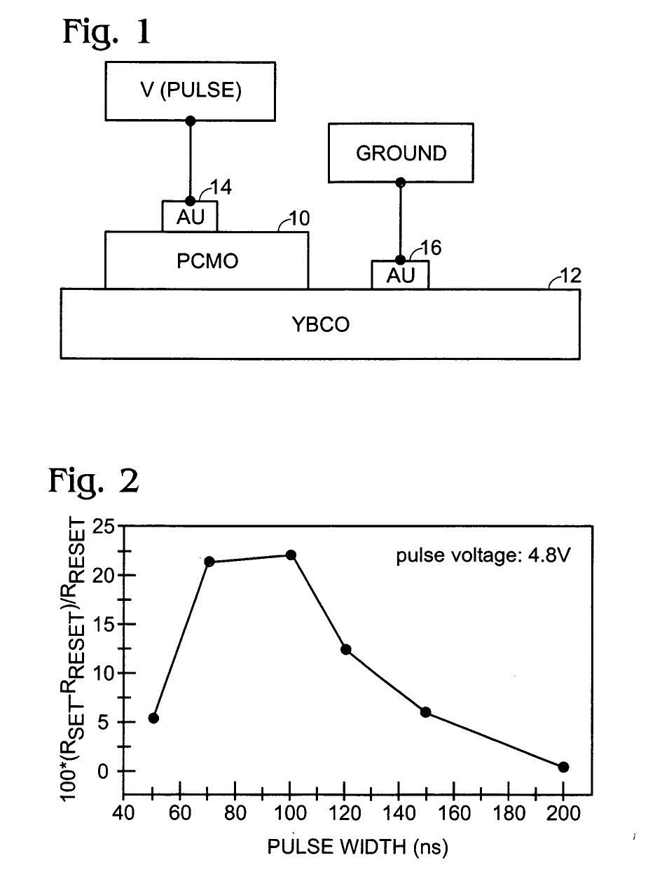

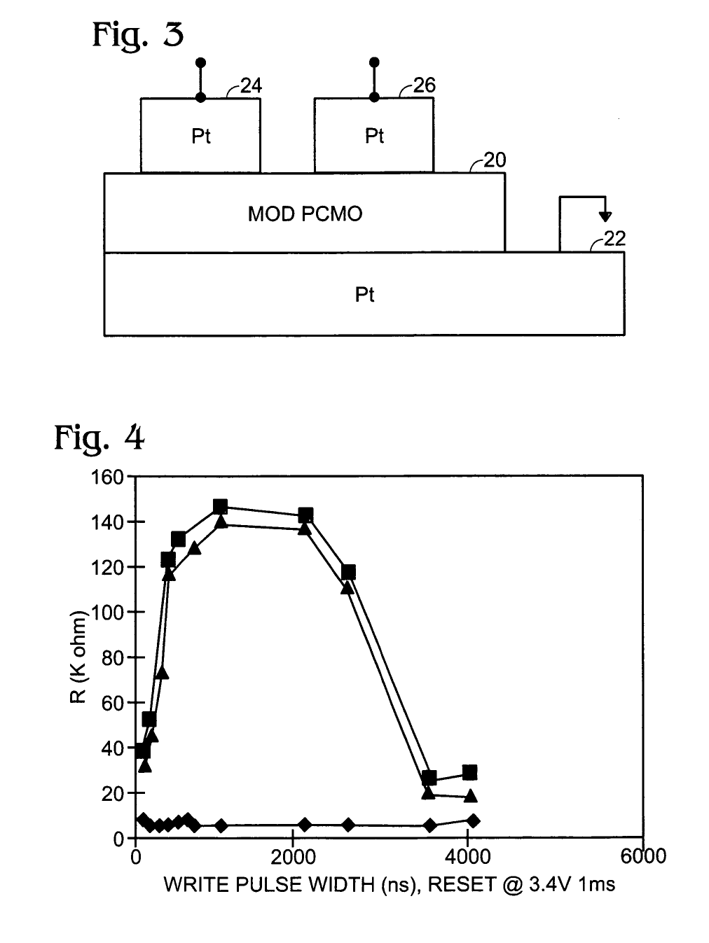

Since the first report of electrical programmable resistance switch resistor as non-volatile memory resistor by Liu et al., supra, a large number of investigations into electric-pulse induced resistive (EPIR) switch effect have been published. Many theories have been posited as to why materials exhibit EPIR properties. None of these theories, however, are sufficient to explain why memory resistors can be programmed to a high resistance state with narrow-width electric pulse, while a large-width electric pulse may re-set the resistance to a low resistance state. The range of high resistance state programming electric pulse width, which is referred to herein as programming pulse width window (PPWW) is a function of material quality. The PPWW of a good crystalline EPIR is very small as compared to that of a poor crystalline EPIR. This is shown in FIG. 1 and FIG. 3, where the EPIR material is Pr_{0.7}Ca_{0.3}MnO₃ (PCMO). In FIG. 1, PCMO 10 is epitaxially grown on YₓBa₂Cu₃O₇₋ₓ (YBCO) 12, and is predominantly a single crystal material. Gold terminals 14, 16 are provided. In FIG. 3, PCMO 20 is spin-coated (MOD) onto a platinum substrate 22, and is predominantly amorphous. Platinum terminals 24, 26 are provided. The PPWW of a FIG. 1-type epitaxially-grown PCMO structure is shown in FIG. 2, and is only about 100 ns. The PPWW of a FIG. 3-type structure of spin-coated PCMO is shown in FIG. 4, and is greater than 3000 ns. The PPWW suggests that the switching phenomenon is not caused by any ionic diffusion or conventional deep trap effect.

The key to the physical mechanism of resistance random access memory (RRAM) is the electric-pulse induced resistive switch effect. The electrical property during programming is a transient phenomenon. When an electrical pulse is applied to a two-terminal semiconductor, or a semi-insulator element having metal electrodes on each end, electrons are injected from the cathode into the resistor. The electrical carrier transport equation is given by:

$$\frac{ⅆ n ( x , t )}{ⅆ t} = D \frac{{\partial }^{2} n ( x , t )}{\partial {x}^{2}} + μ E \frac{\partial n ( x , t )}{\partial x} \qquad ( 1 )$$

The boundary conditions are:

$$n ( 0 , t ) = {n}_{c} exp ( - \frac{t}{{τ}_{0}} ) + {n}_{0} ; n ( {\partial }_{0} , t ) = {n}_{0} ; n ( x , 0 ) = {n}_{0} \qquad ( 2 )$$

Where n(x,t) is the electron density at a distance x from cathode at time t; where n_{c}, and n₀ are electron densities at the cathode at the onset of the pulse and the equilibrium electron density at a distance far from the cathode, respectively.

Solving Eq. (1), subject to the boundary conditions of Eq. (2), yields:

$$n ( x , t ) = {n}_{c} exp ( - \frac{t}{{τ}_{0}} ) erfc ( \frac{x - μ Et}{2 \sqrt{Dt}} ) + {n}_{0} \qquad ( 3 )$$

Equation 3 indicates that, at the onset of the electric pulse applied to the resistor there is a packet of electrons injected into the resistor from the cathode. The density of this electron packet decreases exponentially with time, having a time constant τ₀. Thus when the width of the electric pulse is much longer than the time constant τ₀ the density of the electron packet is very small. With the presence of a high density electron packet, the field distribution in the resistor is very non-uniform and has a very low field intensity in the high density electron packet region and a high field intensity where the electron density is low. On the other hand, when the electron density in the electron packet is very low, the electric field is fairly uniform through the resistor. The resistance change is limited in the vicinity of cathode.

Without additional qualification, it is concluded that the mechanism of resistance change is as following:
1. A high density of non-equilibrium electrons in a low field region localizes valence electrons. This turns the memory resistor to the “high resistance state”.
2. A high electric field intensity de-localizes the localized valence electrons. This turns the memory resistor to the “low resistance state”.

Memory materials which may be used for electric-pulse induced resistive switch effect programmable resistors must exhibit the above two conditions. The memory materials must have an inner orbital which has less than a full quota of electrons and a narrow outer conduction orbital. A large number of non-equilibrium electrons is forced from the outer valence electron orbital to occupy the unfilled quota of electrons in the inner orbital, electron-photon interaction bonding localizes the valence electrons, and the resistance of the memory resistor increases. The outer orbital has no free electrons after the dissipation of the electron packet. The valence electrons are trapped in the inner orbital in a rather conventional trap state, which is why a resistor exhibits a long charge retention time.

When there is a high electrical field intensity, the coulomb effect of the electric field de-localizes the localized electrons, and the memory resistor returns to low resistance state. If the width of the programming pulse is much longer than the relaxation time constant τ₀ the density of the electron packet is small and the field intensity at the cathode region increases. As a result, the localized valence electrons are de-localized and the memory resistor remains in a low resistance state.

When the inner orbital of a transition metal has less than a full quota of electrons, the transition metal oxide, either doped or undoped, also has a very narrow conductive d-electron orbital. Therefore, all doped and undoped transition metal oxide exhibits electric pulse programmable resistance property and may be used as RRAM memory materials.

The RRAM electrode material pays an important role in resistance change. Any conductive material cathode is able to inject a high density of electron packets into the RRAM material. The criteria to determine whether a material is suitable for use in a RRAM is the amplitude of the electric pulse and the length of the electron packet relaxation time. An ohmic contact cathode may able to inject a high density of electron in response to a large electric pulse, but have a very short relaxation time. As a result, the PPWW is too small for any practical electrical circuit.

The electrode where the resistance change may occur therefore requires a barrier. The barrier may be a Shottky barrier or a thin insulator barrier. A bipolarity programming RRAM requires a no-barrier electrode and a barrier electrode. For uni-polarity programming RRAM, either one barrier electrode and one no-barrier electrode, or two barrier electrodes are required.

Thus, a method for selecting a memory material and an electrode material for use in an RRAM has been disclosed. It will be appreciated that further variations and modifications thereof may be made within the scope of the invention as defined in the appended claims.

I claim:

1. A method of selecting a memory material and an associated electrode material for use in a RRAM device, comprising:
selecting a memory material having an inner orbital having less than a full quota of electrons and a narrow, outer conductive orbital; and
selecting an associated electrode material for injecting a packet of electrons into the selected memory material when subjected to a narrow-width electric pulse, and which recovers the packet of electrons when subjected to a large-width electric pulse.

2. The method of claim 1 wherein said selecting a memory material includes selecting a memory material wherein the memory material has a high density of non-equilibrium electrons in a low field region which localizes valence electrons, turning the memory resistor to a “high resistance state”; and which has a high electric field intensity which de-localizes the localized valence electrons, turning the memory resistor to a “low resistance state”.

3. The method of claim 1 wherein said selecting a memory material includes selecting a memory material which is a transition metal oxide.

4. The method of claim 1 wherein said selecting a memory material includes selecting a memory material which has a long relaxation time.

5. The method of claim 1 wherein said selecting an associated electrode material includes selecting an electrode material and providing a barrier for the electrode material on at least one electrode in the RRAM.

6. The method of claim 5 wherein the RRAM is a bipolar programmable RRAM and wherein said providing a barrier for the electrode material includes providing a no-barrier electrode and a barrier electrode.

7. The method of claim 6 wherein said providing a barrier electrode includes providing a barrier taken from the group of barriers consisting of a Shottky barrier and an insulator barrier.

8. The method of claim 5 wherein said selecting an associated electrode material includes selecting an electrode material and providing a barrier for the electrode material on at least one electrode in the RRAM includes providing an electrode/barrier combination taken from the group of electrode/barrier combinations consisting of a no-barrier electrode and a barrier electrode and two barrier electrodes.

9. The method of claim 8 wherein said providing a barrier electrode includes providing a barrier taken from the group of barriers consisting of a Shottky barrier and an insulator barrier.
